(19) United States
(12) Patent Application Publication
(10) Pub. No.: US 2020/0274395 A1
(43) Pub. Date: Aug. 27, 2020

(54) WIRELESS POWER RECEIVING UNIT WITH SELF-REGULATING RECTIFIER

(71) Applicant: Maps, Inc., Seoul (KR)

(72) Inventors: Jong Tae HWANG, Seoul (KR); Hyun Ick SHIN, Seoul (KR); Sung Min PARK, Seoul (KR); Min Jung KO, Seoul (KR); Dong Su LEE, Dongducheon-si (KR); Jong Hoon LEE, Seongnam-si (KR); Ki Woong JIN, Anyang-si (KR); Joon RHEE, Seoul (KR)

(73) Assignee: Maps, Inc., Seoul (KR)

(21) Appl. No.: 16/092,326

(22) PCT Filed: Apr. 7, 2017
(86) PCT No.: PCT/KR2017/003806

§ 371 Date: Oct. 9, 2018

(30) Foreign Application Priority Data
Apr. 15, 2016 (KR) 10-2016-0046309

(51) Int. Cl. H02J 50/12; H02M 7/06; H03H 7/01; H02J 7/02

(52) U.S. Cl. CPC H02J 50/12; H02J 7/02; H03H 7/0115; H02M 7/066

(57) ABSTRACT

Provided is a wireless power receiving unit with a self-regulation rectifier. In one embodiment, the wireless power receiving unit includes a resonator configured to receive wireless power; and a self-regulation rectifier unit including a rectifier configured to apply a rectifier output voltage to a load by converting alternating-current (AC) power received from the resonator into direct-current (DC) power, and a switching device located at a rear end of the rectifier and configured to self-regulate the rectifier output voltage.

### TECHNICAL FIELD

The present invention relates to a power transmitting and receiving technique, and more particularly, to a wireless power transmitting and receiving technique.

### BACKGROUND ART

A wireless power transmission system includes a power transfer unit (hereinafter referred to as ‘PTU’) transmitting power wirelessly and a power receiving unit (hereinafter referred to as ‘PRU’) receiving power wirelessly. The PRU receives power through a resonator consisting of an inductor L and a capacitor C. In this case, alternating current (AC) having the same frequency as power transmitted from the PTU flows through the resonator. Generally, a final output signal is generated in the form of a stable direct-current (DC) signal, and supplied to a load. To this end, a rectifier is needed. The rectifier converts an AC signal into an unregulated DC signal. The unregulated DC signal is converted into a smooth DC voltage signal by a power converter, and the smooth DC voltage signal is supplied to the load. The power converter has a 2-stage structure regardless of the type thereof, and the power transmission efficiency of the PRU is determined by the duct of the efficiency of the rectifier and the efficiency of the power converter. Accordingly, high power transmission efficiency is difficult to obtain when the power converter has a multistage structure.

### DISCLOSURE

### Technical Problem

In one embodiment, a wireless power receiving unit capable of increasing power transmission efficiency by generating stable output power only through a rectifier and a resonator without additionally using a power converter is proposed.

### Technical Solution

One aspect of the present invention provides a wireless power receiving unit including a resonator configured to receive wireless power; and a self-regulation rectifier unit which includes a rectifier configured to apply a rectifier output voltage to a load by converting alternating-current (AC) power received from the resonator into direct-current (DC) power, and a switching device configured to self-regulate the rectifier output voltage, the switching device being located at a rear end of the rectifier.

In one embodiment, the switching device may include a first output terminal connected to an input terminal of the rectifier, a second output terminal connected to the ground, and an input terminal to which a control signal generated from the rectifier output voltage is input.

In one embodiment, when the switching device is turned on, an antenna current may be dispersed and thus a current flowing through the switching device may be less than the antenna current.

In one embodiment, the switching device may receive a control signal for turning on the switching device and reduce the rectifier output voltage by blocking supply of power from the rectifier to the load when the rectifier output voltage increases, and may receive a control signal for turning off the switching device and increase the rectifier output voltage by allowing the supply of power from the rectifier to the load when the rectifier output voltage reduces. The switching device may be separated from an inductor of the resonator and thus a voltage thereof may be low.

In one embodiment, the wireless power receiving unit may further include a controller configured to turn the switching device on or off according to the rectifier output voltage. The controller may generate a reference voltage by comparing the reference voltage with an output voltage.

In one embodiment, the resonator may include an inductor, a first capacitor configured to directly return a current to the inductor, and a second capacitor configured to supply a current to the load by returning the current via the rectifier. A ratio between a capacitance of the first capacitor and a capacitance of the second capacitor may be controlled through the turning on or off of the switching device such that a total capacitance of the first capacitor and the second capacitor is kept constant. The capacitance of the second capacitor may be a times that of the first capacitor (here, a represents a real number greater than 1).

Another aspect of the present invention provides a wireless power receiving unit including a resonator having an inductor of which one terminal is connected to the ground, a first capacitor connected in series to the inductor, and a second capacitor connected in series to the inductor and connected in parallel with the first capacitor and including a self-regulation rectifier unit having a first controlled rectifier and a second controlled rectifier which are configured to self-regulate rectifier output voltages to be applied to a load. The first controlled rectifier includes a first input node connected to the first capacitor of the resonator, a first output node through which a first rectifier output voltage is output, a first control node to which a first control voltage generated from the first rectifier output voltage is input, and a first ground node connected to the ground. The second controlled rectifier may include a second input node connected to the second capacitor of the resonator, a second output node through which a second rectifier output voltage is output, a second control node to which a second control signal generated from the second rectifier output voltage is input, and a second ground node connected to the ground.

In one embodiment, the first and second controlled rectifiers may respectively control the first and second rectifier output voltages by adjusting a ratio between a capacitance of the first capacitor and a capacitance of the second capacitor such that a total capacitance of the first capacitor and the second capacitor of the resonator is kept constant. The capacitance of the first capacitor and the capacitance of the second capacitor may be the same. The capacitance of the first capacitor may be ½^{N} times that of the second capacitor (here, N represents a positive integer).

Another aspect of the present invention provides a wireless power receiving unit including a resonator having an inductor of which one terminal is connected in series to a first capacitor and another terminal is connected to a first controlled rectifier, a first capacitor connected in series to the inductor, and a second capacitor connected in series to the inductor and the first capacitor and including a self-regulation rectifier unit having the first controlled rectifier and a second controlled rectifier which are configured to self-regulate rectifier output voltages to be applied to a load. The first controlled rectifier includes a first input node connected to the inductor, a first output node through which a first rectifier output voltage is output, a first control node to which a first control voltage generated from the first rectifier output voltage is input, and a first ground node connected to the ground. The second controlled rectifier includes a second input node connected to the second capacitor of the resonator, a second output node through which a second rectifier output voltage is output, a second control node to which a second control signal generated from the second rectifier output voltage is input, and a second ground node connected to the ground.

In one embodiment, the first and second controlled rectifiers may respectively control the first and second rectifier output voltages by adjusting a ratio between a capacitance of the first capacitor and a capacitance of the second capacitor while keeping a total capacitance of the first capacitor and the second capacitor of the resonator constant.

### Advantageous Effects

According to one embodiment, a power receiving unit (PRU) can generate a stable output voltage through a self-regulation rectifier. In this case, a high-voltage switching device is needed to connect a switching device to an antenna, but the switching device can be operated with a low-voltage as the antenna and the switching device are separated from each other. Furthermore, a decrease in efficiency and heating of the switching device when an entire antenna current flows through the switching device absorbing antenna current can be prevented by controlling a current flowing through the switching device when the switching device is on to be lower than the antenna current. In addition, electromagnetic interference (EMI) can be prevented from being influenced by a driving frequency of the switching device by keeping the antenna current constant, and thus an EMI filter is easy to design.

### DESCRIPTION OF DRAWINGS

FIG. 1 is a diagram illustrating a structure of a general power receiving unit (PRU),

FIG. 2 is a diagram illustrating a structure of a PRU receiving power through control of an active device,

FIG. 3 is a graph showing a variation in an antenna current when an output voltage was controlled through a switching operation of the PRU of FIG. 2,

FIG. 4 is a diagram illustrating a structure of a receiver employing a resonance frequency control method using a clock signal,

FIG. 5 is a diagram illustrating a structure of a PRU having a self-output-voltage control function according to an embodiment of the present invention,

FIGS. 6 and 7 are diagrams illustrating a structure of a PRU to increase an output voltage VOUT (to supply power to a load) by turning a switching device M1 off according to an embodiment of the present invention,

FIGS. 8 and 9 are diagrams illustrating a structure of a PRU to reduce the output voltage VOUT (to prevent the supply of power to the load) by turning the switching device M1 on according to an embodiment of the present invention,

FIG. 10 is a diagram illustrating a structure of a PRU including a controller according to an embodiment of the present invention,

FIG. 11 is a waveform diagram illustrating a result of a simulation in which an output voltage VOUT was controlled in the PRU of FIG. 10 when a load current changed from 0 to 200 mA,

FIG. 12 is a waveform diagram of driving signals of a switching device M1 of the PRU of FIG. 10,

FIG. 13 is a diagram illustrating a structure of a controlled rectifier unit (hereinafter referred to as ‘CRU’) including a rectifier and a switching device according to an embodiment of the present invention,

FIG. 14 is a diagram illustrating a structure of a self-regulation rectifier (hereinafter referred to as ‘SRR’) using two CRUs according to an embodiment of the present invention,

FIG. 15 is a diagram illustrating a structure of an SRR including N CRUs according to an embodiment of the present invention,

FIG. 16 is a diagram illustrating a structure of the SRR of FIG. 15, in which 2^{N} capacitors are distributed,

FIG. 17 is a diagram illustrating a structure of an SRR including a full-wave rectifier according to an embodiment of the present invention, and

FIG. 18 is a diagram illustrating a structure of a PRU including a coupled-ring resonator (CRR) according to an embodiment of the present invention.

### MODES OF THE INVENTION

Advantages and features of the present invention and methods of achieving them will be apparent from embodiments to be described in detail in conjunction with the accompanying drawings. However, the present invention is not limited thereto and may be embodied in many different forms. These embodiments are merely provided so that this disclosure will be thorough and complete and will fully convey the concept of the invention to those of ordinary skill in the art. The present invention should be defined by the claims only. In the drawings, the same reference numerals represent the same elements throughout the drawings.

When embodiments of the present invention are described, well-known functions or constructions are not described in detail if it is determined that they would obscure the invention due to unnecessary detail. Terms which will be described below are defined in consideration of functions in embodiments of the present invention and thus may be defined differently according to a user or operator's intention, precedents, or the like. Accordingly, the terms used herein should be defined on the basis of the whole context of the present invention. Hereinafter, embodiments of the present invention will be described in detail.

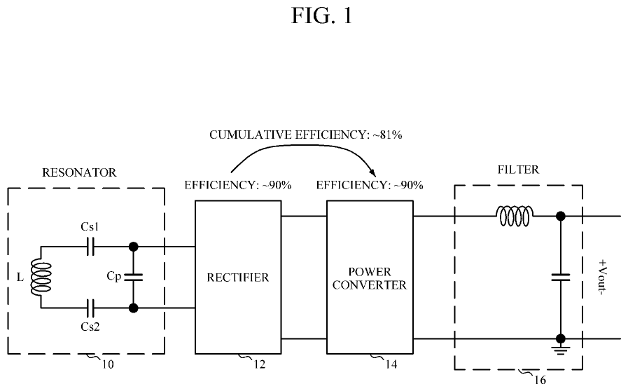

FIG. 1 is a diagram illustrating a structure of a general power receiving unit (PRU).

Referring to FIG. 1, the PRU includes a resonator 10, a rectifier 12, a power converter 14, and a filter 16.

The PRU receives radio energy from a power transfer unit (PTU) through the resonator 10 which includes an inductor L and capacitors Cs1 and Cs2. In this case, alternating current having the same frequency as the radio energy from the PTU flows through the resonator 10. The rectifier 12 obtains a final output in the form of a stable direct-current (DC) signal from an alternating-current (AC) signal and supplies the DC signal to a load. To this end, the rectifier 12 converts the AC signal into an unregulated DC signal. A smooth DC voltage Vout is generated from the unregulated DC signal by the power converter 14, and supplied to the load. A type of the power converter 14 is not limited, and the power converter 14 may be, for example, a buck-type power converter, a boost-type power converter, or a linear-type power converter.

The power converter 14 has a 2-stage structure regardless of the type thereof, and the efficiency of the PRU is determined by a product of the efficiency of the rectifier 12 and the efficiency of the power converter 14. For example, as illustrated in FIG. 1, when maximum efficiency of rectifier 12 is 90% and maximum efficiency of the power converter 14 is 90%, cumulative efficiency is reduced to a maximum of 81%. Accordingly, high efficiency is difficult to achieve when the power converter 14 has a multistage structure.

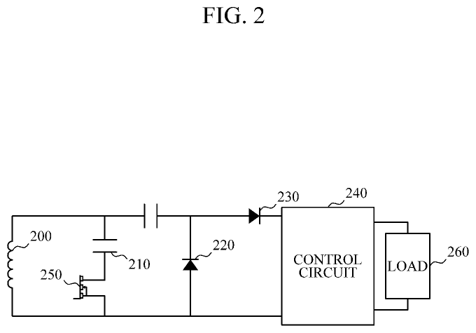

FIG. 2 is a diagram illustrating a structure of a PRU receiving power through control of an active device.

Referring to FIG. 2, the PRU receives energy through a resonator including an inductor 200 and a capacitor 210. The inductor 200 has an inductance equivalent to that of an antenna (not shown). Thereafter, a rectifier including diodes 220 and 230 change an AC signal to a DC signal and then supplies the energy to the load 260. At this time, a control circuit 240 controls an active device 250 to control a voltage to be applied to the load 260. In this method, an additional power converter is not needed unlike in the method described above with reference to FIG. 1, and a rectifier output voltage may be controlled by a single-stage rectifier. However, the active device 250 may operate as a resistor and thus efficiency may be low. In addition, a voltage of the antenna is proportional to receiver sensitivity and a power level of the PTU. In some cases, the voltage approaching several hundreds of volts may be generated. Accordingly, the active device 250 connected to the antenna should have a high withstand voltage to withstand such a high voltage.

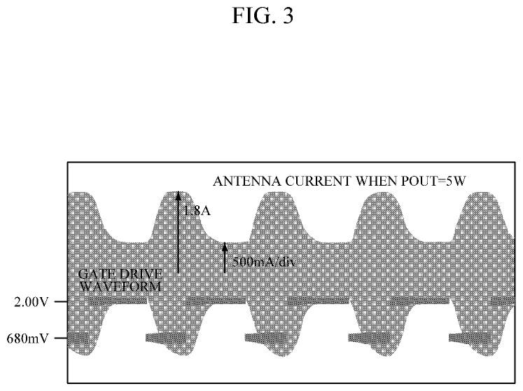

FIG. 3 is a graph showing a variation in antenna current when an output voltage was controlled through a switching operation of the PRU of FIG. 2.

Referring to FIG. 3, a metal-oxide-semiconductor field-effect transistor (MOSFET) device is used as a linear device in the circuit of FIG. 2, and there are many problems with heating of the MOSFET device due to power consumption. Thus, a gate is driven by applying a pulse to operate the MOSFET device as a switching device. In this case, although the amount of heat generated from the MOSFET device may he reduced, an antenna current may he modulated as illustrated in FIG. 3.

In detail, switching of the MOSFET device is controlled using a gate drive waveform to keep an output voltage constant when power of 5 W is consumed by a load and an output voltage is controlled. When the MOSFET device is turned on, the capacitor 210 of FIG. 2 changes a resonance frequency and thus the antenna current is reduced. That is, the antenna current is increased when the current is supplied to the load and is reduced when an output voltage is reduced by turning the MOSFET device on. Thus, it appears that the antenna current is modulated according to the gate drive waveform. Such a change in a current waveform may be understood to mean that output power generated by the PTU changes. Accordingly, an operating condition of a circuit of the PTU may be changed, and thus stable operations may be influenced thereby and noise frequency is generated by being modulated according to the gate drive waveform. Accordingly, electromagnetic interference (EMI) is influenced by the gate drive waveform and thus a circuit capable of suppressing EMI may be difficult to implement.

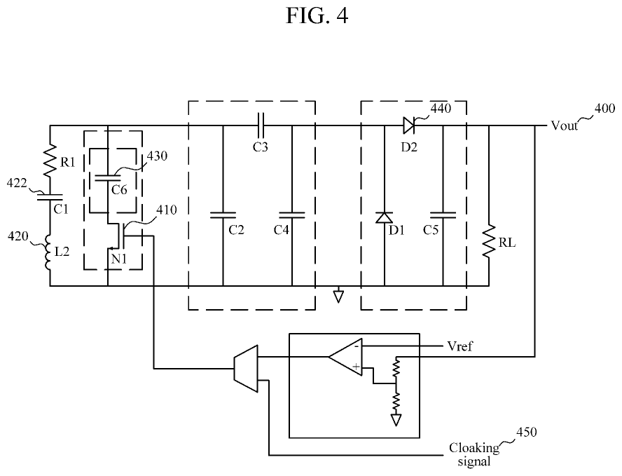

FIG. 4 is a diagram illustrating a structure of a receiver employing a resonance frequency control method using a clock signal.

Referring to FIG. 4, an output voltage Vout 400 is adjusted to a desired voltage through control of a switching device N1 410 using an additional clock signal 450. The method of FIG. 4 is similar to that of FIG. 2 except that the switching device N1 410 is located at a rear end of a resonator including an inductor L2 420 and a capacitor C1 422.

When the switching device N1 410 is turned on, an entire current of the resonator flows through the switching device N1 410 and thus there may be problems with power consumption of the switching device N1 410 as described above with reference to FIG. 2. Furthermore, in the method of FIG. 4, when the switching device N1 410 is on, capacitors C1 422 and C6 430 change a resonance frequency. However, when a capacitance of the capacitor C6 430 is far higher than that of the capacitor C1 422, the resonance frequency may not be significantly changed. Accordingly, the amount of the current flowing through the switching device N1 410 may be very large.

When the capacitance of the capacitor C6 430 is reduced, the resonance frequency is increased and thus the resonance current may be reduced but voltages applied to opposite ends of the capacitor C6 430 may be significantly increased. In this case, current may be supplied to a load by turning a diode D2 440 of a rectifier on. When the switching device N1 410 is on, a current of an antenna is absorbed by the switching device N1 410 to prevent the diode D2 440 from being turned on, thereby reducing an output voltage. However, when the capacitance of the capacitor C6 430 is extremely low, this function is not performed and thus an output voltage cannot be regulated.

An output may be preferably controlled by a single-stage rectifier in terms of efficiency as described above with reference to FIGS. 2 to 4 but the following problems should be fixed to achieve performance of the output being practically used.

(1) Use of low-voltage devices: low-voltage devices should be used to reduce costs and use a low-voltage semiconductor manufacturing process,

(2) modulation of antenna current: a current of an antenna should be kept relatively constant even when an output is controlled so that an operation of a PTU may be stabilized and an effect of a control signal on EMI may be reduced, and

(3) power consumption: power consumption of a device used to control an output voltage should be reduced to increase efficiency and suppress generation of heat.

The present invention suggests a PRU structure to fix the above-described three problems.

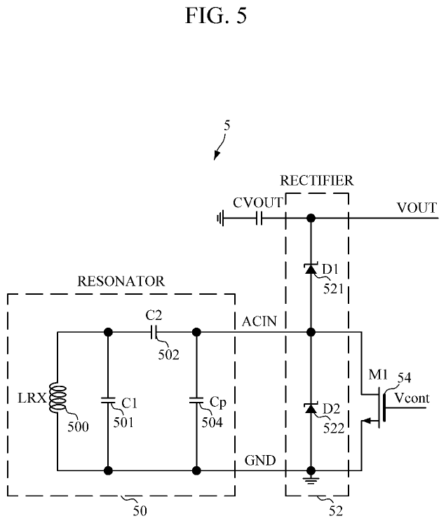

FIG. 5 is a diagram illustrating a structure of a PRU having a self-output-voltage control function according to an embodiment of the present invention.

Referring to FIG. 5, a PRU 5 according to an embodiment includes a resonator 50, a rectifier 52, and a switching device M1 54.

The resonator 50 includes an inductor LRX 500 and capacitors C1 501, C2 502 and Cp 504. The inductor LRX 500 is obtained by modeling an antenna configured to receive power. The capacitors C1 501 and C2 502 are capacitors configured to determine a resonance frequency of the PRU 5. The capacitor C2 502 may be connected in series to the inductor LRX 500, and the capacitor C1 501 may be connected in series to the inductor LRX 500 and connected in parallel to the capacitor C2 502. The capacitor C1 501 is a capacitor which returns current directly to the inductor LRX 500. The capacitor C2 502 is a capacitor which supplies current to a load by returning the current via the rectifier 52. The capacitor Cp 504 is not directly related to wireless power transmission but may prevent parasitic oscillation at a rectifier input terminal ACIN.

The rectifier 52 converts an AC input into a DC output and may be a half-wave rectifier including diodes D1 521 and D2 522 as illustrated in FIG. 5.

The switching device M1 54 controls an output voltage VOUT of the rectifier 52. Generally, when the switching device M1 54 is turned on by applying a control voltage Vcont which is higher than a threshold voltage thereto, the output voltage VOUT of the rectifier 52 may be reduced. Accordingly, an output may be controlled to improve efficiency without an additional power converter.

In one embodiment, the switching device M1 54 includes a first output terminal connected to the rectifier input terminal ACIN, a second output terminal connected to the ground, and an input terminal to which a control signal Vcont for self-regulating the output voltage VOUT of the rectifier 52 is input. When the switching device M1 54 is on, an antenna current is dispersed, and thus a current flowing through the switching device M1 54 is less than the antenna current.

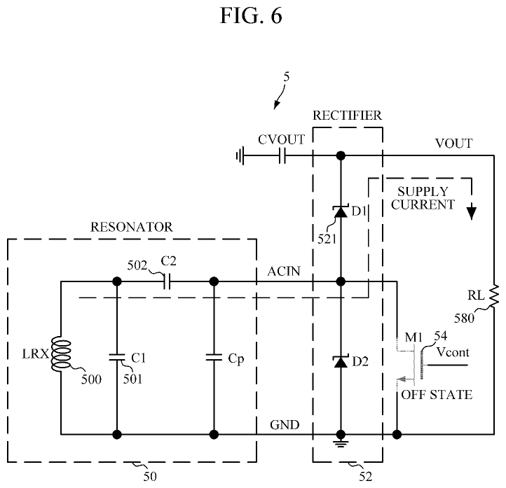

The output voltage VOUT of the rectifier 52 is kept constant by the switching device M1 54. For example, when the output voltage VOUT of the rectifier 52 increases, a control signal for turning the switching device M1 54 on is input to the switching device M1 54, and the switching device M1 54 blocks the supply of power to the load from the rectifier 5, thereby reducing the output voltage VOUT of the rectifier 52. In contrast, when the output voltage VOUT of the rectifier 52 reduces, a control signal for turning the switching device M1 54 off is input to the switching device M1 54, and the switching device M1 54 allows the supply of power to the load from the rectifier 5, thereby increasing the output voltage VOUT of the rectifier 52. Thus, the output voltage VOUT of the rectifier 52 is kept constant. Adjustment of the output voltage VOUT constant through self-regulation of the PRU of FIG. 5 will be described with reference to FIGS. 6, 7, 8, and 9 below.

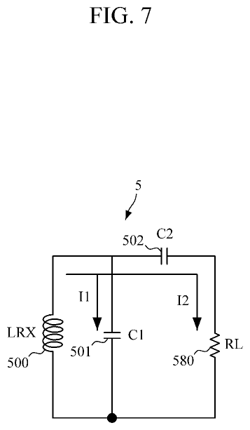

FIGS. 6 and 7 are diagrams illustrating a structure of a PRU to increase an output voltage VOUT (to supply power to a load) by turning a switching device M1 54 off according to an embodiment of the present invention.

If the output voltage VOUT is lower than or equal to a desired voltage, a diode D1 521 carries power and transmits the power to the load by turning off the switching device M1 54 (see FIG. 6). The circuit of FIG. 6 is equivalent to that of FIG. 7.

Referring to FIGS. 6 and 7, a current of an antenna is divided into a current I1 and a current I2, and the current I1 and the current I2 respectively flow through capacitors C1 501 and C2 502. When a resistance value of a load resistor RL 580 is not high, i.e., when high power consumption is needed, a resonance frequency is determined by Equation 1 below.

$$f = \frac{1}{2 π \sqrt{L R X ( C 1 + C 2 )}} \qquad [ Equation 1 ]$$

When an Alliance for Wireless Power (A4WP) receiver for an A4WP PTU using a frequency of 6.78 MHz is manufactured, an inductance of an inductor LRX 500 and capacitances of the capacitors C1 501 and C2 502 are determined such that a resonance frequency of the A4WP receiver is 6.78 MHz.

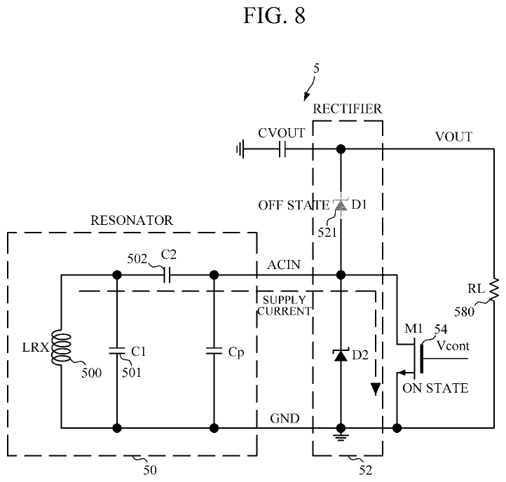

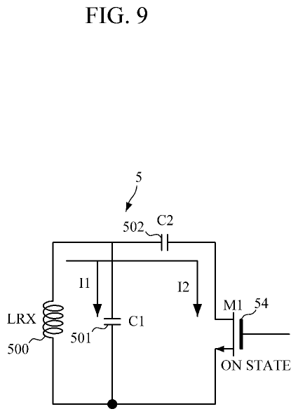

FIGS. 8 and 9 are diagrams illustrating a structure of a PRU to reduce the output voltage VOUT (to prevent the supply of power to the load) by turning the switching device M1 on according to an embodiment of the present invention.

When the output voltage VOUT is higher than a desired voltage, the switching device M1 54 is turned on to prevent the supply of power as an output as illustrated in FIG. 8. Accordingly, the diode D1 521 is off and thus the load disappears. In this case, the circuit of FIG. 8 is equivalent to that of FIG. 9.

When the switching device M1 54 is turned on, a resistance component may be controlled to be very small. Thus, when an equivalent resistance of the switching device M1 54 is very low, a resonance frequency is as expressed in Equation 1 above. Accordingly, in any case, the resonance frequency does not significantly change when considered in terms of an antenna LRX 500.

In FIGS. 6 and 7, the resistor RL 580 is connected in series to the capacitor C2 502 but when the diode D1 521 is on, the load requires power, and thus the resistance value of the resistor RL 580 may not be very high. When power is not consumed by the load, the resistance value of the resistor RL 580 may be very high. In this case, the output voltage VOUT increases, and thus the switching device M1 54 is turned on. Thus, the PRU is operated as illustrated in FIGS. 8 and 9 and a resistance component connected in series to the capacitor C2 502 is not large in any case. That is, states of a resonator in the above two cases are almost the same and thus an antenna current is kept constant. Accordingly, a condition allowing a PTU to stably operate regardless of whether the switching device M1 54 is on or off is secured and thus the antenna current does not significantly change, as illustrated in FIG. 3, and EMI is not influenced by a driving frequency of the switching device M1 54. Accordingly, an EMI filter is easy to design.

During a normal operation, the PRU operates as illustrated in FIGS. 6 and 7 and thus a rectifier input voltage ACIN is almost the same as the sum of a forward voltage and the output voltage VOUT when the diode D1 521 is on. The forward voltage is about 0.7 V when a general diode is used and is about 0.3 V when a schottky junction diode is used. Thus, the rectifier input voltage ACIN may be substantially the same as the output voltage VOUT. When the switching device M1 54 is turned on to reduce the output voltage VOUT, the rectifier input voltage ACIN is almost the same as a ground voltage. Thus, in any case, the rectifier input voltage ACIN is not excessively higher than the output voltage VOUT. Accordingly, a device capable of withstanding a withstand voltage, e.g., the output voltage VOUT, may be used as the switching device M1 54, and thus it is not necessary to use a device capable of withstanding an overvoltage more than needed.

In FIGS. 8 and 9, if capacitances of capacitors C1 501 and C2 502 are the same when the switching device M1 54 is on, a current I1 and a current I2 are most the same. That is, only half an antenna current flows through the switching device M1 54. The entire antenna current flows through the switching device N1 410 in FIG. 4, whereas only half the antenna current flows through a switching device according to the present invention. If, when the switching device M1 54 is turned on, an on-resistor is Ron, a peak current of an antenna is Ip, and a current is in a sine-wave form, power consumption of the on-resistor Ron may be expressed by Equation 2 below.

$$P = \frac{{( Ip / 2 )}^{2} R o n}{2} = \frac{1}{4} \times \frac{I {p}^{2} R o n}{2} \qquad [ Equation 2 ]$$

As shown in Equation 2, the power consumption may be reduced to about ¼ of power consumption when an entire current flows through the switching device N1 410. When C2=a×C1, i.e., when a capacitance of the capacitor C2 502 is set to be a times less than that of the capacitor C1 501 (here, a represents a real number), Equation 2 may be changed to Equation 3 below.

$$P = \frac{1}{{( 1 + a )}^{2}} \times \frac{I {p}^{2} R o n}{2} \qquad [ Equation 3 ]$$

That is, when the real number a is increased, the power consumption may be further reduced. Similarly, a current to be supplied to a load may be reduced to correspond to the reduction in the power consumption, and thus, a may be set to 1 or more when the amount of power consumed by the load is small.

As described above, all the three problems to be solved in the present invention may be fixed by the structure suggested herein.

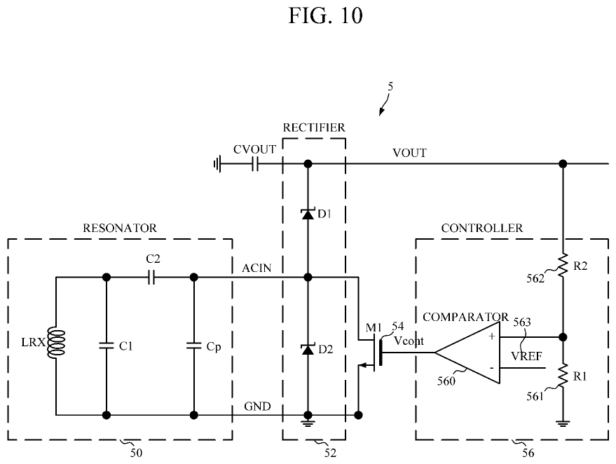

FIG. 10 is a diagram illustrating a structure of a PRU including a controller according to an embodiment of the present invention.

Referring to FIG. 10, a PRU 5 further includes a controller 56, as compared to the PRU 5 of FIG. 5. The controller 56 includes a comparator 560, resistors R1 561 and R2 562 for sensing an output voltage VOUT, and a reference voltage source VREF 563. If a condition of VOUT×R1/(R1+R2)>VREF is satisfied, an output Vcont of the comparator 560 is high, and a switching device M1 54 is turned on, and thereby the output voltage VOUT is reduced. Accordingly, the output voltage VOUT is controlled by (1+R2/R1)×VREF.

Although a structure of the comparator 560 is briefly described herein, a circuit enabling the switching device M1 54 to perform zero-voltage switching or a circuit having an additional function of adding hysteresis to the comparator 560 to prevent the comparator 560 from operating at extremely high speeds may be included in the comparator 560.

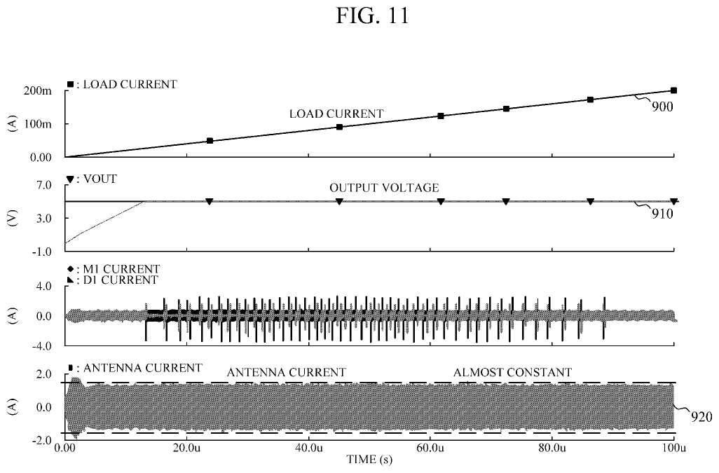

FIG. 11 is a waveform diagram illustrating a result of a simulation in which an output voltage VOUT was controlled in the PRU of FIG. 10 when a load current changed from 0 to 200 mA.

Referring to FIGS. 10 and 11, the simulation was conducted in which the controller 56 was set to regulate an output voltage VOUT 910 to 5 V while a resonator was set to operate at a frequency of 6.78 MHz. As illustrated in FIG. 11, although a load current 900 changed to 200 mA, the output voltage VOUT 910 was controlled to 5 V. The reason why the output voltage VOUT 910 was low at an initial stage was that a discharged rectifier capacitor CVOUT was being charged. An antenna current 920 was kept constant even when the load current 900 changed.

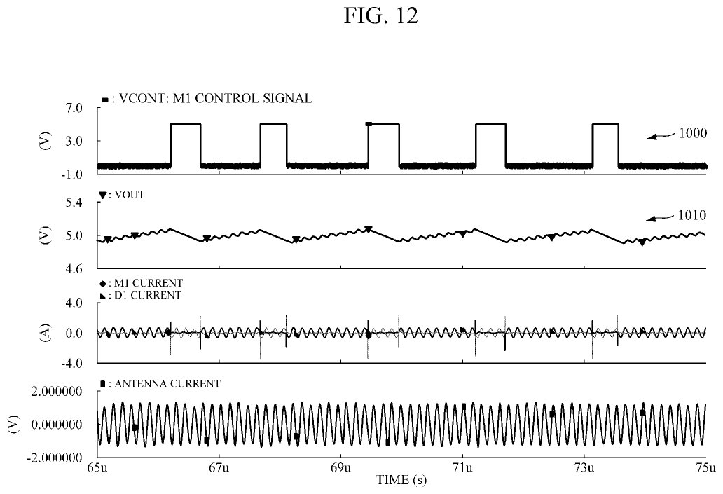

FIG. 12 is a waveform diagram of driving signals of a switching device M1 of the PRU of FIG. 10.

Referring to FIGS. 10 and 12, an output voltage VOUT 1010 was reduced when the switching device M1 was turned on by a high-level switching device control signal 1000 and was increased by turning the switching device M1 off by a low-level switching device control signal 1000 when the output voltage VOUT 1010 reduced.

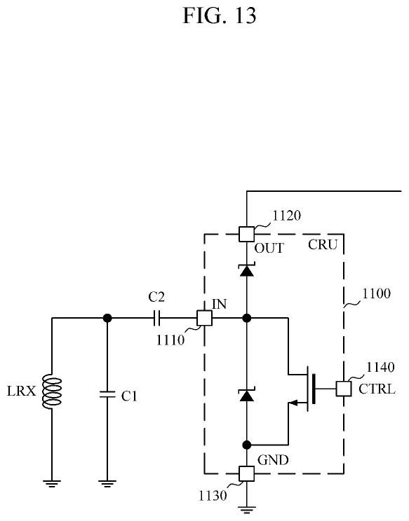

FIG. 13 is a diagram illustrating a structure of a controlled rectifier unit (hereinafter referred to as ‘CRU’) including a rectifier and a switching device according to an embodiment of the present invention.

Referring to FIG. 13, a rectifier and a switching device are defined together as a CRU 1100. In this case, the rectifier may correspond to the rectifier 52 of FIG. 5, and the switching device may correspond to the switching device M1 54 of FIG. 5.

In one embodiment, the CRU 1100 includes an input node IN 1110 to which a rectifier input voltage ACIN is input, an output node OUT 1120 through which a rectifier output voltage VOUT is output, a control node CTRL 1130 to which a control signal is input, and a ground node GND 1140 connected to the ground.

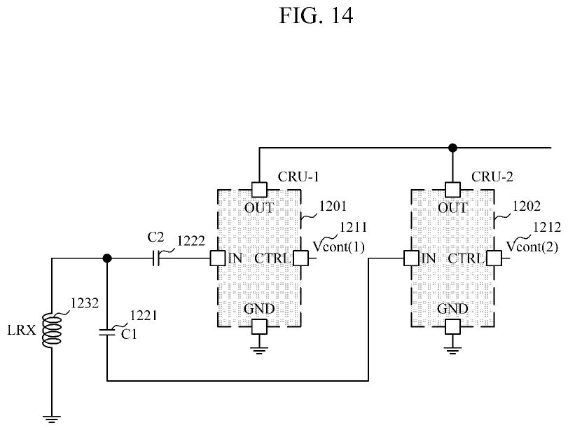

FIG. 14 is a diagram illustrating a structure of a self-regulation rectifier (hereinafter referred to as ‘SRR’) using two CRUs according to an embodiment of the present invention.

Referring to FIG. 14, the CRU of FIG. 13 may be modified into the SRR of FIG. 14 using two CRUs 1201 and 1202. A first control signal Vcont1 1211 is supplied to the first CRU 1201, and a second control signal Vcont2 1212 is supplied to the second CRU 1202.

When the second control signal Vcont2 1212 is at a high level, an operation of the SRR is not significantly different from that of the CRU of FIG. 13. However, when Vcont 1 1211=Vcont 2 1212=0, both of the capacitors C1 1221 and C2 1222 may be used as devices for supplying energy an output, and thereby more energy may be supplied. Accordingly, when C1 1221=C2 2 1222, antenna energy may be controlled in three ways, e.g., the entire antenna energy may be supplied, half the antenna energy may be supplied, or the antenna energy may not be supplied. However, in this case, a resonance frequency is determined by capacitances of the capacitors C1 1221 and C2 1222 and an inductance of an inductor LRX 1232.

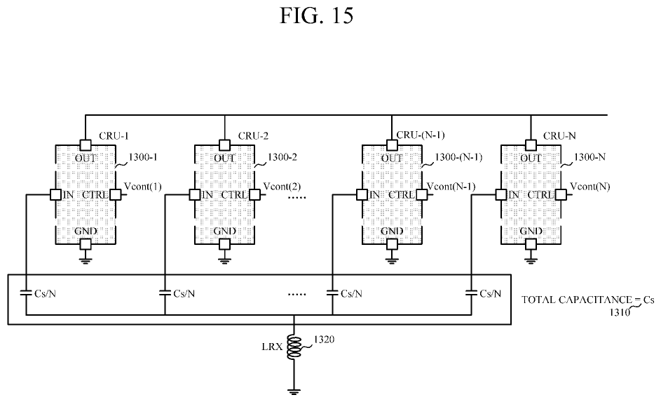

FIG. 15 is a diagram illustrating a structure of an SRR including N CRUs according to an embodiment of the present invention.

Referring to FIG. 15, when N CRUs 1300-1, 1300-2, . . . , 1300-N−1, and 1300-N are used (here, N represents a positive integer), a resonance frequency is determined by a capacitance of a capacitor Cs 1310 and an inductance of an inductor LRX 1320, and Cs/N capacitors are connected to the CRUs 1300-1, 1300-2, . . . , 1300-N−1, and 1300-N. Control voltages Vcont 1, Vcont 2, . . . , Vcont(N−1), and Vcont(N) are respectively applied to the CRUs 1300-1, 1300-2, . . . , 1300-N−1, and 1300-N. In this case, if the control voltage Vcont 1=H and the control voltages Vcont 2 to Vcont(N)=L, energy supplied to a load is 1/N, and a current to be supplied to the load is increased by 1/N whenever each of the control voltages Vcont 2 to Vcont(N) goes high. Accordingly, an output voltage VOUT may be more precisely controlled.

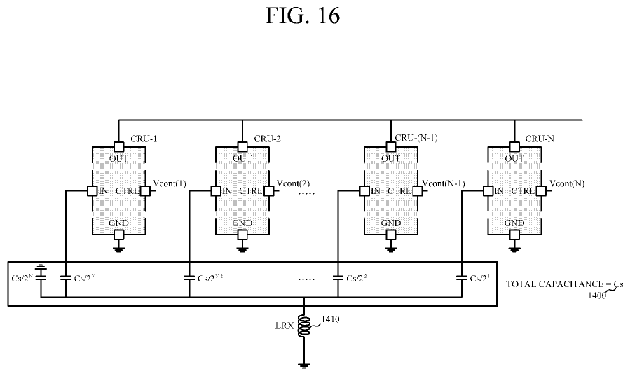

FIG. 16 is a diagram illustrating a structure of the SRR of FIG. 15, in which 2^{N} capacitors are distributed.

Referring to FIG. 16, when capacitors Cs 1400 are distributed in a 2^{N} form (here, N represents a positive integer), a current to be supplied to a load may be finely controlled by a small number of devices. In this case, a total capacitance of the capacitors is Cs, as in FIG. 15, and a resonator frequency is determined by a capacitance of a capacitor Cs 1400 and an inductance of an inductor LRX 1410.

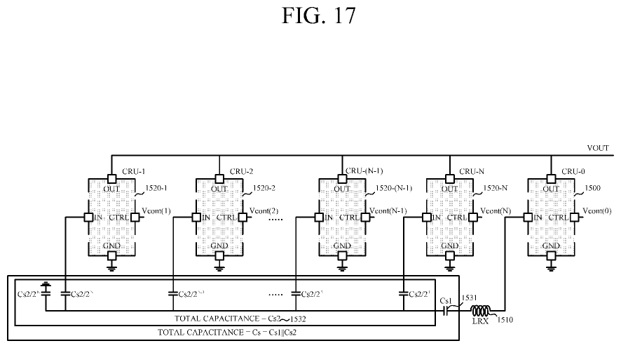

FIG. 17 is a diagram illustrating a structure of an SRR including a full-wave rectifier according to an embodiment of the present invention.

Referring to FIGS. 5, 15 and 16, one terminal of an antenna is at a ground potential, and thus it may be understood that basically, a half-wave rectifier operation is combined with a control function. The combination of the control function and the half-wave rectifier operation may be implemented in the form of full wave rectifier. For example, as illustrated in FIG. 17, a full wave rectifier may be embodied by adding a CRU-0 1500 and connecting another terminal of an antenna LRS 1510 to an input terminal of the CRU-0 1500.

When the full-ware rectifier is embodied as described above, more power may be supplied to a load and thus control voltages Vcont0 to Vcont(N) may be controlled to selectively control a desired current to the load. In this case, a total capacitance of capacitors connected to a CRU-1 1520-1, a CRU-2 1520-2, . . . , CRU-(N−1) 1520-(N−1), and CRU-N 1520-N is Cs2 1532 and a capacitor Cs1 1531 is connected in series to the antenna LRX 510. A resonance frequency is determined by a capacitance of the capacitor Cs1 1531 connected in series to the antenna LRX 1510, and a total capacitance is Cs1∥Cs2=Cs1×Cs2/(Cs1+Cs2). Accordingly, the resonance frequency is determined by an inductance of the antenna LRX 1510 and the total capacitance of Cs1 1531∥Cs2 1532.

FIG. 17 illustrates an example of an SRR in which capacitors are divided into a 2^{N} form. The SRR of FIG. 17 may be easily changed to that of FIG. 16.

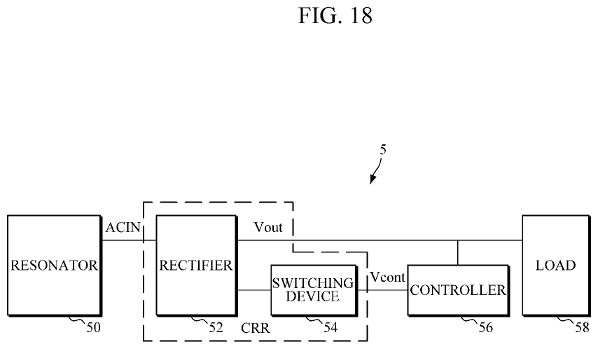

FIG. 18 is a diagram illustrating a structure of a PRU including a coupled-ring resonator (CRR) according to an embodiment of the present invention.

Referring to FIG. 18, a PRU 5 includes a resonator 50, a controller 56, a load 58, and a CRR 59. The CRR 59 includes a rectifier 52 and a switching device 54.

The rectifier 52 applies a rectifier output voltage VOUT to the load 58 by converting AC power received from the resonator 50 into DC power. The switching device 54 is located at a rear end of the rectifier 52 and self-regulates the rectifier output voltage VOUT. The switching device 54 may include a first output terminal connected to an input terminal of the rectifier 52, a second output terminal connected to the ground, and an input terminal to which a control signal generated from a rectifier output voltage VOUT is input.

The controller 56 turns the switching device 54 on or off by supplying a control signal Vcont to the switching device 54. For example, when the rectifier output voltage VOUT increases, the switching device 54 reduces the rectifier output voltage VOUT by blocking the supply of power from the rectifier 52 to the load 58 according to a control signal for turning the switching device 54 on. In contrast, when the rectifier output voltage VOUT decreases, the switching device 54 increases the rectifier output voltage VOUT by allowing the supply of power from the rectifier 52 to the load 58 according to a control signal for turning off the switching device 54. Accordingly, the rectifier output voltage VOUT may be kept constant. When the switching device 54 is turned on, an antenna current is dispersed, and thus a current flowing through the switching device 54 is less than the antenna current.

The switching device 54 configured to control the rectifier output voltage VOUT may be separated from an antenna and thus be operated with a low voltage. Furthermore, a current to flow through the switching device 54 when the switching device 54 is turned on is set to be less than the antenna current, and thus it is possible to prevent a decrease in efficiency and heating of the switching device 54 when the entire antenna current flows through the switching device 54 absorbing the antenna current. In addition, the antenna current may be kept constant and thus EMI is not influenced by a driving frequency of the switching device 54. Accordingly, an EMI filter is easy to design.

The present invention has been described above with respect to embodiments thereof. It will be apparent to those of ordinary skill in the technical field to which the present invention pertains that the present invention may be embodied in different forms without departing from essential features thereof. Accordingly, the embodiments set forth herein should be considered in a descriptive sense only and not for purposes of limitation. The scope of the present invention is defined in the appended claims other than the above description, and all differences falling within the same range as the present invention should be understood as being included in the present invention.

1. A wireless power receiving unit comprising:
a resonator configured to receive wireless power; and
a self-regulation rectifier unit,
wherein the self-regulation rectifier unit comprises:
a rectifier configured to apply a rectifier output voltage to a load by converting alternating-current (AC) power received from the resonator into direct-current (DC) power; and
a switching device configured to self-regulate the rectifier output voltage, the switching device being located at a rear end of the rectifier.

2. The wireless power receiving unit of claim 1, wherein the switching device comprises:
a first output terminal connected to an input terminal of the rectifier;
a second output terminal connected to the ground; and
an input terminal to which a control signal generated from the rectifier output voltage is input.

3. The wireless power receiving unit of claim 1, wherein, when the switching device is on, an antenna current is dispersed and thus a current flowing through the switching device is less than the antenna current.

4. The wireless power receiving unit of claim 1, wherein the switching device receives a control signal for turning on the switching device and reduces the rectifier output voltage by blocking supply of power from the rectifier to the load when the rectifier output voltage increases, and receives a control signal for turning off the switching device and increases the rectifier output voltage by allowing the supply of power from the rectifier to the load when the rectifier output voltage reduces.

5. The wireless power receiving unit of claim 1, wherein the switching device is separated from an inductor of the resonator and thus a voltage thereof is low.

6. The wireless power receiving unit of claim 1, further comprising a controller configured to turn the switching device on or off according to the rectifier output voltage.

7. The wireless power receiving unit of claim 6, wherein the controller comprises a comparator configured to generate a reference voltage by comparing the reference voltage with an output voltage.

8. The wireless power receiving unit of claim 1, wherein the resonator comprises:
an inductor;
a first capacitor configured to directly return a current to the inductor; and
a second capacitor configured to supply a current to the load by returning the current via the rectifier,
wherein a ratio between a capacitance of the first capacitor and a capacitance of the second capacitor is controlled through the turning on or off of the switching device such that a total capacitance of the first capacitor and the second capacitor is kept constant.

9. The wireless power receiving unit of claim 8, wherein the capacitance of the second capacitor is a times that of the first capacitor, wherein a represents a real number greater than 1.

10. A wireless power receiving unit comprising:
a resonator comprising:
an inductor of which one terminal is connected to the ground;
a first capacitor connected in series to the inductor; and
a second capacitor connected in series to the inductor and connected in parallel with the first capacitor; and
a self-regulation rectifier unit comprising a first controlled rectifier and a second controlled rectifier which are configured to self-regulate rectifier output voltages to be applied to a load,
wherein the first controlled rectifier comprises:
a first input node connected to the first capacitor of the resonator;
a first output node through which a first rectifier output voltage is output;
a first control node to which a first control voltage generated from the first rectifier output voltage is input; and
a first ground node connected to the ground, and
the second controlled rectifier comprises:
a second input node connected to the second capacitor of the resonator;
a second output node through which a second rectifier output voltage is output;
a second control node to which a second control signal generated from the second rectifier output voltage is input; and
a second ground node connected to the ground.

11. The wireless power receiving unit of claim 10, wherein the first and second controlled rectifiers respectively control the first and second rectifier output voltages by adjusting a ratio between a capacitance of the first capacitor and a capacitance of the second capacitor such that a total capacitance of the first capacitor and the second capacitor of the resonator is kept constant.

12. The wireless power receiving unit of claim 10, wherein a capacitance of the first capacitor and a capacitance of the second capacitor are the same.

13. The wireless power receiving unit of claim 10, wherein a capacitance of the first capacitor is ½^{N} times that of the second capacitor, wherein N represents a positive integer.

14. A wireless power receiving unit comprising:
a resonator comprising:
an inductor of which one terminal is connected in series to a first capacitor and another terminal is connected to a first controlled rectifier;
a first capacitor connected in series to the inductor; and
a second capacitor connected in series to the inductor and the first capacitor; and
a self-regulation rectifier unit comprising the first controlled rectifier and a second controlled rectifier which are configured to self-regulate rectifier output voltages to be applied to a load,
wherein the first controlled rectifier comprises:
a first input node connected to the inductor;
a first output node through which a first rectifier output voltage is output;
a first control node to which a first control voltage generated from the first rectifier output voltage is input; and
a first ground node connected to the ground, and
the second controlled rectifier comprises:
a second input node connected to the second capacitor of the resonator;
a second output node through which a second rectifier output voltage is output;
a second control node to which a second control signal generated from the second rectifier output voltage is input; and
a second ground node connected to the ground.

15. The wireless power receiving unit of claim 14, wherein the first and second controlled rectifiers respectively control the first and second rectifier output voltages by adjusting a ratio between a capacitance of the first capacitor and a capacitance of the second capacitor while keeping a total capacitance of the first capacitor and the second capacitor of the resonator constant.
